(19) United States
(12) Patent Application Publication
(10) Pub. No.: US 2007/0300140 A1
(43) Pub. Date: Dec. 27, 2007

(54) Electronic device having a plurality of modes of operation

(75) Inventors: Jakke Makela, Turku (FI); Jukka Linjama, Espoo (FI)

Correspondence Address: HARRINGTON & SMITH, PC, 4 RESEARCH DRIVE, SHELTON, CT, 06484-6212, US

(73) Assignee: Nokia Corporation

(21) Appl. No.: 11/434,631

(22) Filed: May 15, 2006

(51) Int. Cl. H04L 1/00; G06F 11/00; G08C 25/00; H03M 13/00

(52) U.S. Cl. 714/799

(57) ABSTRACT

An electronic device including a display, a first user input, for enabling access to a plurality of functions, a second user input, and a controller, operable, in response to an input, to change the mode of operation of the device from a first, active mode of operation, in which the controller is operable to enable a user access to a plurality of functions, to a second, restricted mode of operation in which the controller is operable to disable user access to the plurality of functions, and operable, in response to an input via the second user input, to change the mode of operation of the device from the second, restricted mode of operation to a third, restricted mode of operation in which the controller is operable to disable user access to the plurality of functions and is operable to present information not presentable in the second restricted mode of operation.

### FIELD OF THE INVENTION

Embodiments of the present invention relate to an electronic device having a plurality of modes of operation, a computer program and a method for switching the device between the plurality of modes of operation. In particular they relate to electronic devices having more than one user input.

### BACKGROUND TO THE INVENTION

Electronic devices commonly have an active mode of operation, where a user can use a user input to access the functions of the electronic device and a restricted mode of operation where the user input is non-responsive to user actuation thereby preventing user access to functions of the device. For example, in a cellular radio telephone, it is common for a user to be able to lock the keypad when the phone is not in use so that when the phone is being carried in a pocket or a handbag it cannot perform functions, such as dialing a number, unintentionally but the phone can still receive incoming calls and messages.

Sometimes a user of such devices may wish to briefly access the functions of the device, for example, they may wish to quickly check a piece of information stored in the device. In such circumstances it may be inconvenient for the user of the device to have to exit the restricted mode and enter the active mode.

### BRIEF DESCRIPTION OF THE INVENTION

According to one embodiment of the invention there is provided an electronic device comprising: a display; a first user input, for enabling access to a plurality of functions; a second user input; and a controller operable, in response to an input, to change a mode of operation of the device from a first, active mode of operation, in which the controller is operable to enable user access to a plurality of functions, to a second, restricted mode of operation in which the controller is operable to disable user access to the plurality of functions, and operable, in response to an input via the second user input, to change the mode of operation of the device from the second, restricted mode of operation to a third, restricted mode of operation in which the controller is operable to disable user access to the plurality of functions and is operable to present information not presentable in the second restricted mode of operation.

This provides the advantage that a user can view information without having to enter an active mode of operation. This allows quick access to information and also prevents any functions being performed unintentionally on the information as the device remains in a restricted mode.

In some embodiments of the invention, when the device is in the third, restricted mode of operation, the controller is operable in response to actuation of the second user input, to control the display to present further information not presentable in the second, restricted mode of operation. The second user input may be a detector for detecting a gesture input such as a tap input and the first user input may be a different type of input. Thus the device may have different methods of user input depending on the mode of the device. This provides the advantage that it is clear to the user that if they are using gesture inputs to control the device it is clear that they are still in a restricted mode of operation and no functions can be performed on the information.

According to another embodiment of the invention there is provided a method of controlling an electronic device comprising a display, a first user input, for enabling access to a plurality of functions, a second user input and a controller, the method comprising: detecting a user input when the device is in a first, active mode of operation in which the controller is operable to enable a user access to a plurality of functions; in response to the detection of the user input changing the mode of operation from the first, active mode of operation to a second, restricted mode of operation in which the controller is operable to disable user access to the plurality of functions; detecting a further user input via the second user input when the device is in the second, restricted mode of operation; and, in response to the further user input changing the mode of operation of the device from the second, restricted mode of operation to a third, restricted mode of operation in which the controller is operable to disable user access to the plurality of functions and is operable to control the display to present information not presentable in the second, restricted mode of operation.

According to another embodiment of the invention there is also provided a computer program comprising program instructions for controlling an electronic device, the electronic device having a display, a first user input for enabling access to a plurality of functions, a second user input and a controller, which, when loaded into a processor, provides: means for detecting a user input when the device is in a first, active mode of operation in which the controller is operable to enable a user access to a plurality of functions; means for changing the mode of operation of the device, in response to the detection of the user input, from the first, active mode of operation to a second, restricted mode of operation in which the controller is operable to disable user access to the plurality of functions; means for detecting a further user input via the second user input when the device is in the second, restricted mode of operation; and means for changing the mode of operation of the device, in response to the further user input, from the second restricted mode of operation to a third, restricted mode of operation in which the controller is operable to disable user access to the plurality of functions and is operable to control the display to present information not presentable in the second, restricted mode of operation.

According to another embodiment of the invention there is also provided a method of controlling an electronic device to present information to a user, the electronic device comprising a display, a first user input device and a second user input device, the first user input device having at least one active mode of operation, in which the first input device is operable to enable a user to control the electronic device to perform any of a first plurality of tasks, and a disabled mode of operation in which the first user input device is not operable to enable a user to control the electronic device to perform any of the first plurality of tasks,

the method comprising; activating the disabled mode of the first user input device; detecting a user input via the second user input device; in response to the detection of the input via the second user input device, controlling the display to present a first item of information while the first user input device remains in the disabled mode and the second user input device is operable to control the device to present further items of information.

### BRIEF DESCRIPTION OF THE DRAWINGS

For a better understanding of the present invention reference will now be made by way of example only to the accompanying drawings in which:

FIG. 1. schematically illustrates an electronic device;

FIG. 2. is a mode transition diagram for an electronic device according to an embodiment of the present invention;

FIGS. 3A to 3G. illustrate an embodiment of the present invention in use.

### DETAILED DESCRIPTION OF EMBODIMENTS OF THE INVENTION

The Figures illustrate an electronic device 1 comprising: a display 11, a first user input 13, for enabling access to a plurality of functions, a second user input 15, and a controller 3, operable, in response to an input, to change the mode of operation of the device 1 from a first, active mode of operation, in which the controller 3 is operable to enable a user access to a plurality of functions, to a second, restricted mode of operation in which the controller 3 is operable to disable user access to the plurality of functions, and operable, in response to an input via the second user input 15, to change the mode of operation of the device 1 from the second, restricted mode of operation to a third, restricted mode of operation in which the controller 3 is operable to disable user access to the plurality of functions and is operable to present information not presentable in the second restricted mode of operation.

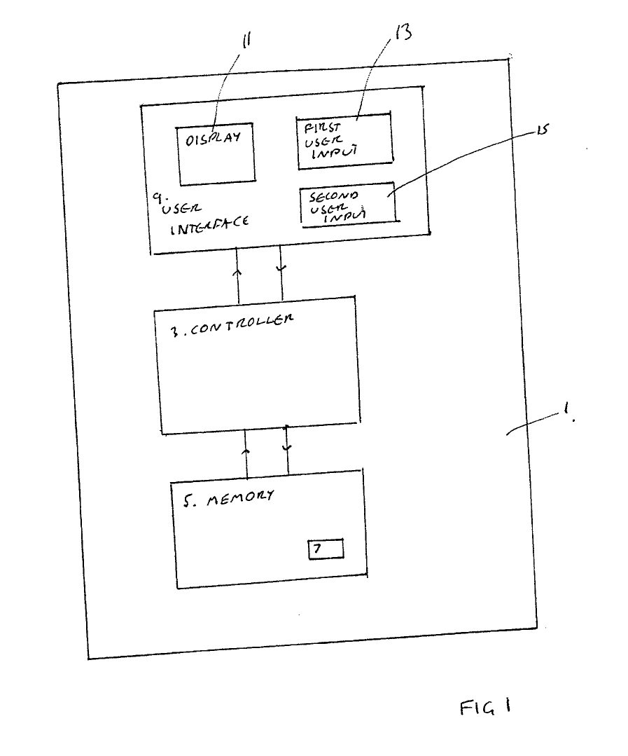

FIG. 1 schematically illustrates an electronic device 1. Only the features referred to in the following description are illustrated. It should, however, be understood that the device 1 may comprise additional features that are not illustrated. The electronic device 1 may be, for example, a personal computer, a personal digital assistant, a mobile cellular telephone, or any other electronic device having a plurality of modes of operation including an active mode and a restricted mode.

The illustrated electronic device 1 comprises: a user interface 9, a memory 5, and controller 3. The user interface 9 comprises a display 11, a first user input 13 and a second user input 15.

The user inputs 13 and 15 may be any means which allow a user to enable access to the functions of the device 1 and input information into the device 1 including, for example, a key pad, a detector for detecting a gesture input, a joystick, a roller, voice recognition means or a touch sensitive region of the display 11. The first user input 13 and the second user input 15 may be different types of input, for example the first user input 13 may be a keypad, while the second user input 15 may be a detector for detecting gesture inputs.

A gesture input may be a tap applied to the device by the user. The detector for detecting the gesture input may be operable to detect a tap applied to any part of the device. The detector may also be operable to distinguish between taps made to various parts of the device.

A gesture input may also be movement of the device, such as shaking or tilting the device, or making a series of motions which imparts a sudden change of momentum to the device.

The detector for detecting the gesture input may be an accelerometer, an inductive pad for detecting the speed of approach of an object such as a user's finger, or a proximity sensor.

The controller 3 is connected to receive input commands from the user inputs 13 and 15 and to provide output commands to the display 11. The controller 3 is also connected to write to and read from the memory 5.

The memory 5 stores computer program instructions 7, which when loaded into the controller 3, enable the controller 3 to control the operation of the device 1 as described below. The computer program instructions 7 provide the logic and routines that enables the electronic device 1 to perform the methods described below.

The computer program instructions 7 may arrive at the electronic device 1 via an electromagnetic carrier signal or be copied from a physical entity such as a computer program product, a memory device or a record medium such as a CD-ROM or DVD.

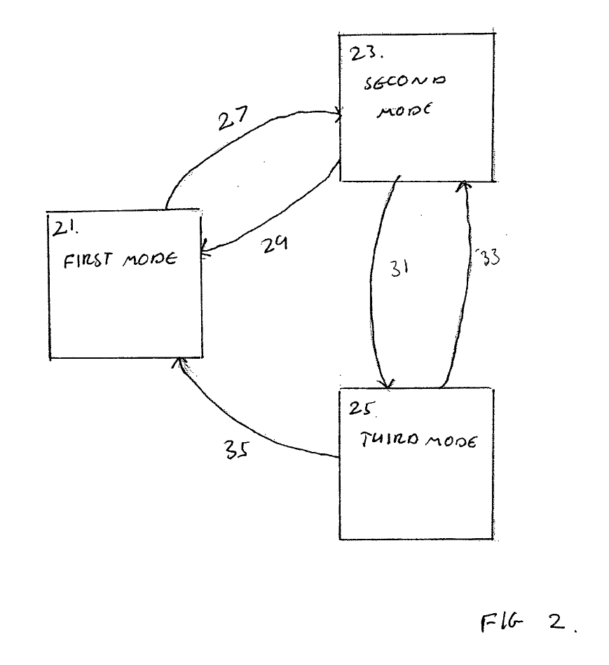

FIG. 2 is a mode transition diagram which schematically illustrates the different modes of operation and the possible transitions between the modes for the electronic device 1 illustrated in FIG. 1.

The first mode 21 is an active mode of operation in which the first user input 13 is operable to enable a user to access a plurality of functions of the electronic device 1. The plurality of functions may include, for example, communications functions which enable the device 1 to communicate in a cellular network, information functions which enable a user to input and store information, camera functions which enable a user to capture and store images.

In some embodiments only the first user input 13 may be operable to enable access to the plurality of functions when the device is in the first mode 21. In other embodiments both the first user input 13 and the second user input 15 may be operable to enable access to the plurality of functions.

The second mode 23 is a restricted mode of operation. In this mode 23 neither of the user inputs 13 and 15 are responsive to enable access to the plurality of functions. However the second user input 15 is operable to detect an input, such as a gesture input, and switch the device 1 from the second mode 23 to the third mode 25.

In some embodiments the user may still have access to a substantially limited range of functions when the device 1 is in the second, restricted mode 23. For example, in embodiments where the device 1 is a cellular radio telephone a user can still access emergency communications functions by dialing an emergency telephone number, such as 911 in the US or 112 in Europe, even when the device 1 is in a restricted mode of operation. Also a user may be able to view a limited amount of information on the display 11 without having to enter an active mode 21. Such information may include an indication of the strength of the cellular network signal, an indication of the power remaining in the battery, an indication that audio alerts have been deactivated and an indication that the device 1 is in a restricted mode.

The third mode 25 is also a restricted mode. As in the second mode 23 the first user input 13 is unresponsive to user actuation except for providing access to a substantially limited range of functions. However, the third mode 25 differs from the second mode 23 in that in the third mode 25 the controller 3 is operable to control the display 11 to display information that cannot be displayed when the device 1 is in the second mode 23.

The information that can be displayed in the third mode 25 may be stored in a menu in the memory 5 of the device 1. The second user input 15 may be operable to enable a user to navigate through the menu and select the information to be displayed.

The information may include information relating to missed telephone calls or received but unread SMS or MMS messages. For example the information could include the time of the missed call or message, and who the missed call or message is from. In some embodiments the controller 3 may be operable to control the display 11 to present the entire contents of the received messages.

When the device 1 is in the third mode 25 the controller 3 is not operable to perform any of the plurality of functions of the device 1 on the information that is displayed on the display 11. That is, the user can view the information but not edit, delete, forward or use the information, for example to make a telephone call. This prevents any functions being performed unintentionally for example dialing a number inadvertently or deleting a piece of information.

The mode of operation of the device 1 can be switched from the first mode 21 to the second mode 23, as indicated by the input 27, and from the second mode 23 to the first mode 21 as indicated by the input 29. The inputs 27 and 29 may be made via the user inputs 13 and 15. For example, if the device 1 is a cellular radio telephone and the first user input 13 is a key pad, inputs 27 and 29 may be actuating the keys in a specific sequence such as a soft key followed by the star key.

The electronic device 1 may be a foldable or slideable device 1 in which case the input 27 may be closing the device, and the input 29 may be opening the device 1.

In some embodiments the inputs 27 and 29 could be external, for example input 27 could be an incoming call and input 29 could be the end of a call.

The mode of operation of the device 1 can be switched from the second mode 23 to the third mode 25, via input 31, but not from the first mode 21 to the third mode 25. Input 31 may be actuation of the second user input 15. In embodiments where the second user input is a detector for detecting a gesture input, the input 31 may be a gesture input such as a tap applied to any part of the device 1.

The mode of operation of the device 1 can be switched from the third mode 25 to the second mode 23, as indicated by input 33, and from the third mode 25 to the first mode as indicated by input 35.

Input 33 may be a user input made via the second user input 15 or it could be the detection, by the controller 3 that no input has occurred for a predetermined amount of time. Input 35 may be actuation of the first user input 13 for example, actuating keys of a keypad in a specific sequence as described above.

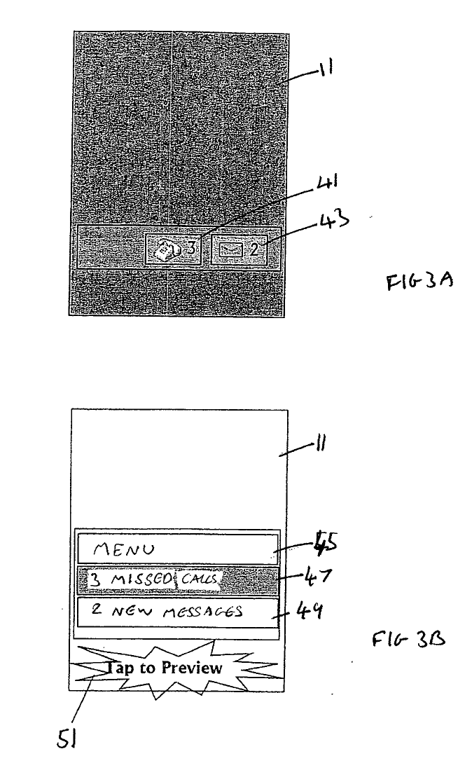

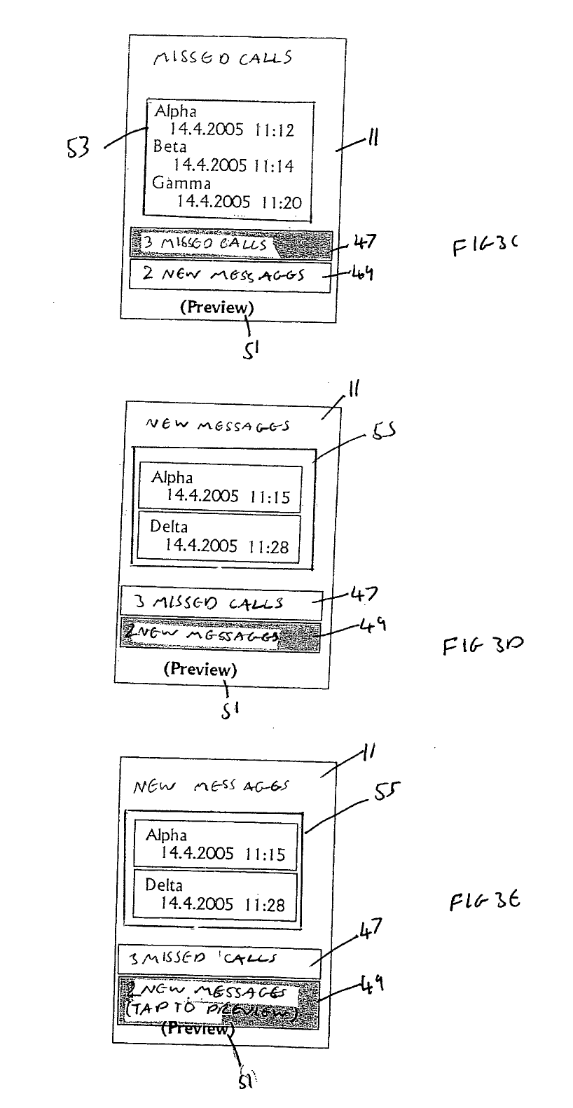

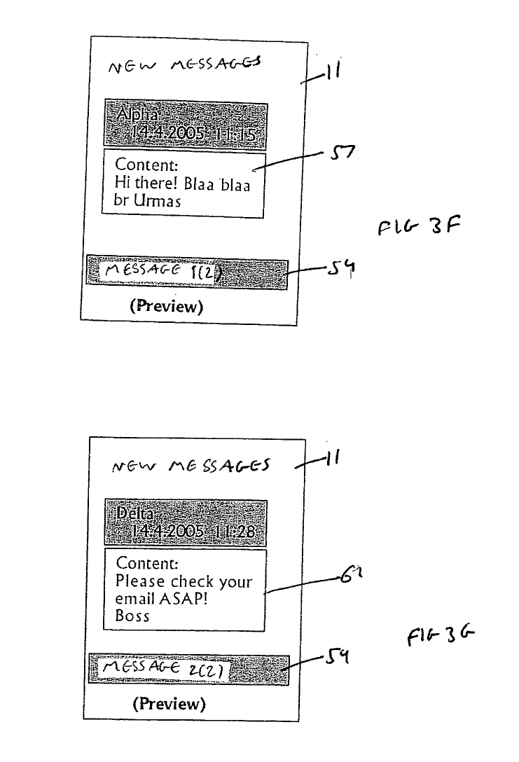

FIGS. 3A to 3G illustrate an embodiment of the invention in use. In this particular embodiment the electronic device 1 is a cellular radio telephone and the second user input 15 is a detector for detecting a tap input. The detector may comprise an accelerometer which can detect a tap applied to any part of the device 1.

FIG. 3A illustrates a display 11 presented to a user when the device 1 is in the second mode 23. Two icons 41 and 43 are displayed on the display 11. Icon 41 represents the number of missed calls the device 1 has received and icon 43 represents the number of received but unread messages the device 1 has received.

If a user wishes to view more information about the missed calls and received messages then the user can enter the third mode 25 of the device 1 by tapping the device 1. The tap may be applied to any part of the device 1. In some embodiments the user may have to tap a specific part of the device 1 for example the top of the device 1.

FIG. 3B illustrates an example of a display 11 presented to a user when the user enters the third mode 25 of operation of the device 1. The display 11 comprises a menu 45 containing a first option 47 relating to the missed calls and a second option 49 relating the received messages. In FIG. 3B the first menu option 47 is highlighted. The user may be able to navigate through the menu 45 using the second user input 15. For example tapping the top of the device 1 will scroll up the list, tapping the bottom of the device 1 will scroll down the list and tapping any other part of the device 1 will select the highlighted option.

Icon 51 indicates that by tapping the device 1 the user will be able to preview the highlighted menu option, that is, they will be able to view information associated with the highlighted menu option but not perform any function on that information. In some embodiments the icon 51 may flash.

FIG. 3C illustrates the display 11 presented to a user after they have selected the menu option 47 relating to missed calls. Information 53 relating to the missed calls is now displayed. The information 53 includes an identification of the caller, and the time and date at which the call was made. In this particular embodiment the menu options 47 and 49 are also displayed, this enables a user to view the information 53 and also continue scrolling through the options without having to return to the display 11 of FIG. 3B.

To view details of the new messages the user must scroll down the list of menu options to highlight the menu option 49 associated with new messages and then select the menu option 49 by tapping the device 1. FIG. 3D illustrates a display 11 presented to the user after they have selected the menu option 49 associated with new messages according to a first embodiment of the invention. Information 55 relating to the new messages is received. This information 55 includes an identification of the sender of each message and the time and date at which each message was received. As in FIG. 3C the menu options 47 and 49 are also displayed together with the information 55.

In other embodiments of the invention the device 1 may be operable to present the contents of the new messages on the display 11 while the device still in the third mode 25. In these embodiments the display will present the display illustrated in FIG. 3E to a user instead of that of FIG. 3D when the user selects the menu option 49 relating to new messages.

FIG. 3E is the same as FIG. 3D except that menu option 49 now indicates that by tapping the device 1 again the user can preview the messages. In some embodiments the tap may have to be made to a specific part of the device 1, for example the right side or the left side.

FIGS. 3F and 3G illustrate the display presented to a user when they have selected to preview the contents of the new messages. In FIG. 3F the first message 57 is presented to the user. The menu options 47 and 49 have been replaced by an icon 59 indicating that the message 57 currently displayed is the first of two new messages.

FIG. 3G illustrates the display presented to the user after they have tapped the device 1 in order to control the device 1 to present the second message 61. FIG. 3G is similar to FIG. 3F except that the first message 57 has been replaced with the second message 61 and the icon 59 now indicates that the message 61 is the second of two messages.

In some embodiments viewing the information does not change the status of the information viewed. For example if a user views the contents of a message when the device 1 is in the third mode 25 then the messages are still classed as new and unread and the icon 43 indicating the number of new and unread messages will not change when the device returns to the second mode 23.

In the described embodiment the user accesses information relating to missed calls and received messages when the device 1 is in the third mode. The user may be also be able to access other information, for example, voice mail, Although embodiments of the present invention have been described in the preceding paragraphs with reference to various examples, it should be appreciated that modifications to the examples given can be made without departing from the scope of the invention as claimed. For example in the embodiments described the information has been presented to the user by being displayed on a display, in other embodiments the information could be presented in other ways for example as an audio output.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1. An electronic device comprising:
a display;
a first user input, for enabling access to a plurality of functions;
a second user input; and
a controller operable, in response to an input, to change a mode of operation of the device from a first, active mode of operation, in which the controller is operable to enable user access to a plurality of functions, to a second, restricted mode of operation in which the controller is operable to disable user access to the plurality of functions, and
operable, in response to an input via the second user input, to change the mode of operation of the device from the second, restricted mode of operation to a third, restricted mode of operation in which the controller is operable to disable user access to the plurality of functions and is operable to present information not presentable in the second restricted mode of operation.

2. An electronic device as claimed in claim 1 wherein when the device is in the third, restricted mode of operation the controller is operable, in response to actuation of the second user input, to control the display to present further information not presentable in the second, restricted mode of operation.

3. An electronic device as claimed in claim 1 wherein when the device is in the third, restricted mode of operation the controller is not operable to edit, delete or forward the displayed information, in response to a user input.

4. An electronic device as claimed in claim 1 wherein when the device is in either of the restricted modes of operation the controller disables access to all communications functions except emergency communications functions.

5. An electronic device as claimed in claim 1 wherein the first user input is a keypad.

6. An electronic device as claimed in claim 1 wherein the first user input is a touch sensitive region of the display.

7. An electronic device as claimed in claim 1 wherein the second user input is a detector for detecting a gesture input.

8. An electronic device as claimed in claim 7 wherein the second user input comprises an accelerometer.

9. An electronic device as claimed in claim 1 wherein the information presented to the user is stored in a menu.

10. An electronic device as claimed in claim 1 wherein the electronic device is a mobile cellular telephone.

11. An electronic device as claimed in claim 1 wherein the electronic device is a personal digital assistant.

12. A method of controlling an electronic device comprising a display, a first user input, for enabling access to a plurality of functions, a second user input and a controller, the method comprising:
detecting a user input when the device is in a first, active mode of operation in which the controller is operable to enable a user access to a plurality of functions;
in response to the detection of the user input changing the mode of operation from the first, active mode of operation to a second, restricted mode of operation in which the controller is operable to disable user access to the plurality of functions;
detecting a further user input via the second user input when the device is in the second, restricted mode of operation; and,
in response to the further user input changing the mode of operation of the device from the second, restricted mode of operation to a third, restricted mode of operation in which the controller is operable to disable user access to the plurality of functions and is operable to control the display to present information not presentable in the second, restricted mode of operation.

13. A method as claimed in claim 12 wherein when the device is in the third, restricted mode of operation the controller is operable, in response to actuation of the second user input, to control the display to present further information not presentable in the second, restricted mode of operation.

14. A method as claimed in claim 12 wherein when the device is in the third, restricted mode of operation the controller is not operable to edit, delete or forward the displayed information, in response to a user input.

15. A method as claimed in claim 12 wherein when the device is in either of the restricted modes of operation the controller disables access to all communications functions except emergency communications functions.

16. A method as claimed in claim 12 wherein the first user input is a keypad.

17. A method as claimed in claim 12 wherein the first user input is a touch sensitive region of the display.

18. A method as claimed in claim 12 wherein the second user input is a detector for detecting a gesture input.

19. A method as claimed in claim 18 wherein the second user input comprises an accelerometer.

20. A method as claimed in claim 12 wherein the information presented to a user is stored in a menu.

21. A computer program comprising program instructions for controlling an electronic device, the electronic device having a display, a first user input for enabling access to a plurality of functions, a second user input and a controller, which, when loaded into a processor, provides:
means for detecting a user input when the device is in a first, active mode of operation in which the controller is operable to enable a user access to a plurality of functions;
means for changing the mode of operation of the device, in response to the detection of the user input, from the first, active mode of operation to a second, restricted mode of operation in which the controller is operable to disable user access to the plurality of functions;
means for detecting a further user input via the second user input when the device is in the second, restricted mode of operation; and
means for changing the mode of operation of the device, in response to the further user input, from the second restricted mode of operation to a third, restricted mode of operation in which the controller is operable to disable user access to the plurality of functions and is operable to control the display to present information not presentable in the second, restricted mode of operation.

22. A physical entity embodying the computer program as claimed in claim 21.

23. An electromagnetic carrier signal carrying the computer program as claimed in claim 21.

24. A method of controlling an electronic device to present information to a user, the electronic device comprising a display, a first user input device and a second user input device,
the first user input device having at least one active mode of operation, in which the first input device is operable to enable a user to control the electronic device to perform any of a first plurality of tasks, and a disabled mode of operation in which the first user input device is not operable to enable a user to control the electronic device to perform any of the first plurality of tasks,
the method comprising;
activating the disabled mode of the first user input device;
detecting a user input via the second user input device;
in response to the detection of the input via the second user input device, controlling the display to present a first item of information while the first user input device remains in the disabled mode and the second user input device is operable to control the device to present further items of information.
